(19) United States
(12) Patent Application Publication
(10) Pub. No.: US 2025/0316487 A1
(43) Pub. Date: Oct. 9, 2025

(54) WAFER CUTTING METHOD

(71) Applicants: HUBEI 3D SEMICONDUCTOR INTEGRATED INNOVATION CENTER CO., LTD., Wuhan, Hubei (CN); HUBEI YANGTZE MEMORY LABORATORIES, Wuhan, Hubei (CN)

(72) Inventors: Tianjian LIU, Wuhan (CN); Yingchao TIAN, Wuhan (CN); Ruixia CAO, Wuhan (CN); Xiaoning REN, Wuhan (CN)

(73) Assignees: HUBEI 3D SEMICONDUCTOR INTEGRATED INNOVATION CENTER CO., LTD., Wuhan, Hubei (CN); HUBEI YANGTZE MEMORY LABORATORIES, Wuhan, Hubei (CN)

(21) Appl. No.: 18/855,627

(22) PCT Filed: Dec. 21, 2022
(86) PCT No.: PCT/CN2022/140771

§ 371 Date: Oct. 9, 2024

(30) Foreign Application Priority Data
Apr. 12, 2022 (CN) 202210376505.2

(51) Int. Cl. H01L 21/304; B23K 26/38; B23K 101/40; H01L 21/3065; H01L 21/3105; H01L 21/66; H01L 21/78; H01L 23/00

(52) U.S. Cl. CPC H01L 21/304; B23K 26/38; H01L 21/3065; H01L 21/31053; H01L 21/78; H01L 22/34; H01L 24/80; B23K 2101/40; H01L 2224/80896; H01L 2924/12042

(57) ABSTRACT

A wafer cutting method, including providing a wafer bonding structure; forming a first oxide layer on a dielectric layer of a topmost wafer of the wafer bonding structure; performing cutting along a scribe lane test structure of the topmost wafer so as to form a first trench in the wafer bonding structure, the first trench penetrating through at least one wafer and exposing a substrate of a bottommost wafer; and filling the first trench with a second oxide layer.

### CROSS-REFERENCE TO RELATED APPLICATION

This application is filed based on and claims priority to Chinese patent application No. 202210376505.2 filed on Apr. 12, 2022, the disclosures of which are hereby incorporated by reference in its entirety.

### TECHNICAL FIELD

The disclosure relates to, but is not limited to a method for wafer dicing.

### BACKGROUND

In the field of semiconductors, with continuous introduction of new process nodes, volumes of transistors become smaller and smaller, a variety of physical limits restrict their further development, and extension of Moore's Law slows down. Giants such as Foundry, IDM and OSAT have shifted their battlefields to the field of advanced packaging one after another, and continuously introduce their own chiplet solutions. Most of current chiplets are connected by micro bumps, with a size of about 10 to 50 μm, and traditional die dicing may still meet process requirements. When the process is further refined, die connection of the chiplet requires a hybrid bonding mode, with a size less than 1 μm, which may greatly increase I/O density and enhance chip performance.

However, hybrid bonding puts extremely strict requirements on chip processing, especially die dicing and surface planarization processes. Traditional die dicing is cutter wheel dicing, resulting in serious edge chipping, cracks and internal stresses; heat affected zone (HAZ) and re-melting problem of laser surface dicing cannot be ignored, either; laser stealth dicing and plasma dicing have strong selectivity on materials, and are slightly weak for dicing of low dielectric-constant (low-k) layers and metals. However, for chip design and manufacturing, metal at a region of a dicing lane is unavoidable. Although a current-emerging combined dicing manner of laser surface dicing and grooving and plasma etching of a silicon (Si) substrate may effectively avoid the above problems, it is only directed to a single wafer. When a dicing object is a multi-layer stacked wafer, layers sandwiched between the low-k layer which needs to be removed by laser grooving and the Si substrate are too thick, and there is serious accumulation of slags, resulting in inability of effectively removing the slags later.

### SUMMARY

The disclosure provides a method for wafer dicing, the method includes the following operations. A wafer bonding structure is provided, here the wafer bonding structure includes at least two wafers stacked in sequence, each of the wafers includes a substrate, a dielectric layer formed on the substrate, and a dicing lane test structure formed in the dielectric layer.

A first oxide layer is formed on a dielectric layer of a topmost wafer of the wafer bonding structure.

Dicing is performed along a dicing lane test structure of the topmost wafer, to form a first trench in the wafer bonding structure, here the first trench penetrates through at least one wafer and exposes a substrate of a bottommost wafer.

Residual slags in the first trench are removed after the first trench is formed.

A second oxide layer is filled in the first trench, here the second oxide layer fully fills the first trench and covers the first oxide layer.

A surface of the second oxide layer is planarized.

A hybrid bonding interface is formed on the second oxide layer.

The second oxide layer in the first trench is removed.

A fixing film is attached to a side of the substrate of the bottommost wafer of the wafer bonding structure, and the side of the substrate is away from the hybrid bonding interface.

The substrate of the bottommost wafer is diced.

In an embodiment, thickness of the first oxide layer may be equal to or greater than 0.05 μm.

In an embodiment, the residual slags in the first trench may be removed by using an etching process.

In an embodiment, the first trench may be formed by using a laser dicing process.

In an embodiment, the first oxide layer and the second oxide layer may be formed by using a chemical vapor deposition (CVD) process.

In an embodiment, the surface of the second oxide layer may be planarized by using a chemical mechanical polishing (CMP) manner.

In an embodiment, the operation of forming the hybrid bonding interface on the second oxide layer may include the following operations.

Vias are formed in the first oxide layer and the second oxide layer, here the vias penetrate through the first oxide layer and the second oxide layer.

Conductive bonding pads are formed in the vias respectively.

In an embodiment, the second oxide layer in the first trench may be removed by using a dry etching process.

In an embodiment, the substrate of the bottommost wafer may be diced by using a plasma dicing process.

### BRIEF DESCRIPTION OF THE DRAWINGS

FIG. 1 is a flowchart of a method for wafer dicing according to an embodiment of the disclosure.

FIG. 2 is a schematic diagram of a wafer bonding structure according to an embodiment of the disclosure.

FIG. 3 is a schematic structural diagram of forming a first oxide layer on the wafer bonding structure according to the embodiment of the disclosure.

FIG. 4 is a schematic structural diagram of forming a first trench according to the embodiment of the disclosure.

FIG. 5 is a schematic structural diagram of removing slags at the bottom of the first trench according to the embodiment of the disclosure.

FIG. 6 is a schematic structural diagram of forming a second oxide layer according to the embodiment of the disclosure.

FIG. 7 is a schematic structural diagram of planarizing the second oxide layer according to the embodiment of the disclosure.

FIG. 8 is a schematic structural diagram of forming vias of a hybrid bonding layer according to the embodiment of the disclosure.

FIG. 9 is a schematic structural diagram of forming conductive bonding pads in the hybrid bonding layer according to the embodiment of the disclosure.

FIG. 10 is a schematic structural diagram of forming a patterned photoresist layer according to the embodiment of the disclosure.

FIG. 11 is a schematic structural diagram of removing the second oxide layer in the first trench according to the embodiment of the disclosure.

FIG. 12 is a schematic structural diagram of attaching a wafer to a fixing film according to the embodiment of the disclosure.

FIG. 13 is a schematic structural diagram of dicing a substrate of a bottommost wafer according to the embodiment of the disclosure.

### DETAILED DESCRIPTION

The method for wafer dicing proposed in the disclosure will be further described in detail below with reference to the drawings and specific embodiments. Advantages and features of the disclosure will be clearer from the following descriptions. It should be noted that all the drawings are made in a very simplified form and use imprecise proportions, and are only intended to conveniently and clearly assist in explaining the purpose of the embodiments of the disclosure.

The inventor found through research that hybrid bonding puts extremely strict requirements on chip processing, especially die dicing and surface planarization processes. Traditional die dicing is cutter wheel dicing, resulting in serious edge chipping, cracks and internal stresses; heat affected zone (HAZ) and re-melting problem of laser surface dicing cannot be ignored, either; laser stealth dicing and plasma dicing have strong selectivity on materials, and are slightly weak for dicing of low dielectric-constant dielectric layers and metals. However, for chip design and manufacturing, metal at a region of a dicing lane is unavoidable. Although a current-emerging combined dicing manner of laser surface dicing and grooving and plasma etching of a silicon (Si) substrate may effectively avoid the above problems, it is only directed to a single wafer. When a dicing object is a multi-layer stacked wafer, layers sandwiched between the low dielectric-constant dielectric layer which needs to be removed by laser grooving and the Si substrate are too thick, and there is serious accumulation of slags, resulting in inability of effectively removing the slags later.

Based on this, core ideas of the embodiments of the disclosure are to provide a wafer bonding structure, here the wafer bonding structure includes at least two wafers stacked in sequence; form a first oxide layer as a protective layer, and form a first trench which penetrates through at least one wafer and exposes a substrate of a bottommost wafer; then form a second oxide layer which fully fills the first trench and covers the first oxide layer, planarize the second oxide layer, and form a planarized hybrid bonding interface; then remove the second oxide layer in the first trench, and dice the substrate of the bottommost wafer, so that the problem where when the multi-layer stacked wafer is diced, layers sandwiched between the low dielectric-constant layer which needs to be removed by laser grooving and the Si substrate are too thick, and accumulation of slags is serious, resulting in inability of effectively removing the slags later, may be solved.

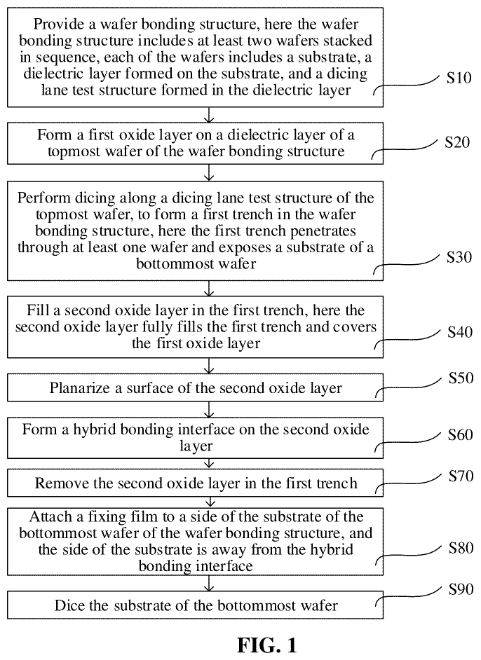

Specifically, with reference to FIG. 1, it is a flowchart of a method for wafer dicing according to an embodiment of the disclosure. As shown in FIG. 1, the disclosure provides a method for wafer dicing, the method includes the following operations S10 to S90.

In operation S10, a wafer bonding structure is provided, here the wafer bonding structure includes at least two wafers stacked in sequence, each of the wafers includes a substrate, a dielectric layer formed on the substrate, and a dicing lane test structure formed in the dielectric layer.

In operation S20, a first oxide layer is formed on a dielectric layer of a topmost wafer of the wafer bonding structure.

In operation S30, dicing is performed along a dicing lane test structure of the topmost wafer, to form a first trench in the wafer bonding structure, here the first trench penetrates through at least one wafer and exposes a substrate of a bottommost wafer.

In operation S40, a second oxide layer is filled in the first trench, here the second oxide layer fully fills the first trench and covers the first oxide layer.

In operation S50, a surface of the second oxide layer is planarized.

In operation S60, a hybrid bonding interface is formed on the second oxide layer.

In operation S70, the second oxide layer in the first trench is removed.

In operation S80, a fixing film is attached to a side of the substrate of the bottommost wafer of the wafer bonding structure, and the side of the substrate is away from the hybrid bonding interface.

In operation S90, the substrate of the bottommost wafer is diced.

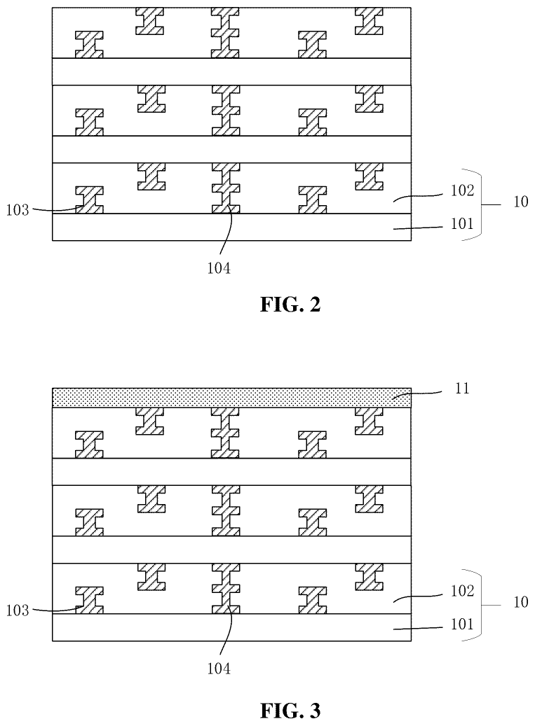

FIG. 2 to FIG. 13 are schematic structural diagrams corresponding to corresponding operations of the method for wafer dicing provided in the embodiment. The method for wafer dicing provided in the embodiment will be described in detail below with reference to FIG. 2 to FIG. 13.

With reference to FIG. 2, in operation S10, a wafer bonding structure is provided, the wafer bonding structure includes at least two wafers 10 stacked in sequence, and the wafer bonding structure may also include multiple wafers 10 stacked in sequence. In the embodiment, for example, the wafer bonding structure includes three wafers stacked in sequence. The wafer 10 includes a dielectric layer 102, a substrate 101, and a dicing lane test structure 104. Device structures (not shown in the figure) are formed in the substrate 101, and the device structures may be Metal Oxide Semiconductor (MOS) devices, sensor devices, memory devices and/or other passive devices. Interconnection structures 103 are formed in the dielectric layer 102, the substrate 101 is provided with a front side and a back side, the interconnection structures 103 cover the front side of the substrate 101, and the interconnection structures 103 are interconnected with the device structures respectively. The dielectric layer 102 may be a single-layer or multi-layer structure, the interconnection structure 103 may be one or more metal layers, and interconnection between different metal layers may be achieved through electrical connectors such as contact plugs, wiring layers, and/or vias, etc. In the embodiment, material of the dielectric layer 102 may be a dielectric material or a low-k dielectric material, such as silicon oxide, silicon nitride, silicon oxynitride, Nitrogen doped Silicon Carbide (NDC), or a combination thereof. Material of the interconnection structure 103 may be a metal material, such as tungsten, aluminum, copper, or a combination thereof.

With reference to FIG. 3, in operation S20, a first oxide layer 11 is formed on a dielectric layer of a topmost wafer. In the embodiment, the first oxide layer 11 is formed by using a chemical vapor deposition (CVD) process, and thickness of the first oxide layer 11 is for example equal to or greater than 0.05 μm. The first oxide layer 11 is used to protect the dielectric layer of the topmost wafer, and is also used as a pattern protective layer in subsequent etching processes, and as a buffer layer in a chemical mechanical polishing (CMP) process.

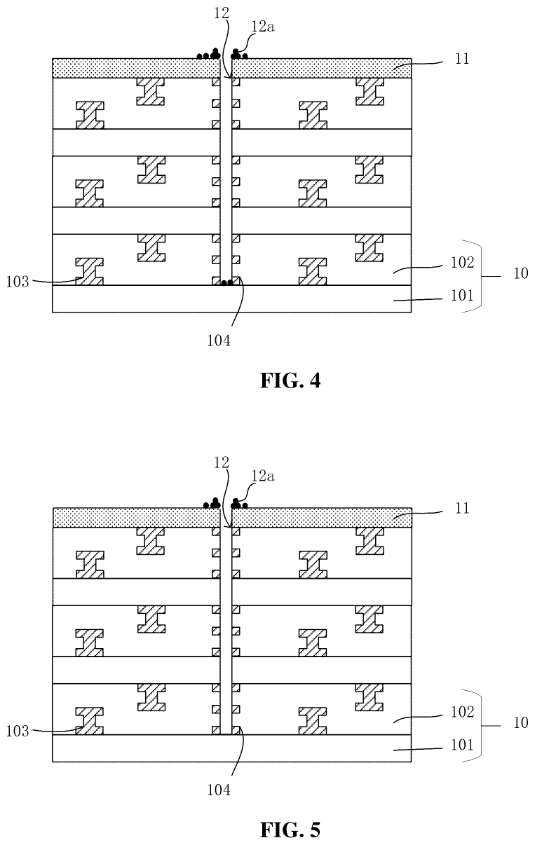

With reference to FIG. 4, in operation S30, dicing is performed along the dicing lane test structure 104, to form a first trench 12. The first trench 12 penetrates through at least one wafer 10 and exposes a substrate 101 of a bottommost wafer. In the embodiment, the first trench 12 is formed by using a laser dicing process. Width of the first trench 12 is less than width of the dicing lane test structure 104. When the dicing lane test structure 104 is diced by laser, a large amount of slags 12a may be formed and cover the bottom of the first trench and the first oxide layer 11 at both sides of the top of the first trench.

With reference to FIG. 5, after operation S30, residual slags 12a in the first trench are removed after the first trench 12 is formed. In the embodiment, the residual slags 12a in the first trench are removed by using an etching process. The etching process includes a wet etching process or a dry etching process. A wet etching solution uses a chemical solution which removes metal, silicon nitride and silicon oxide. Silicon nitride is removed for example by using phosphoric acid (H₃PO₄). Silicon oxide is removed for example by using hydrogen fluoride (HF). Metal is removed for example by using a SCl solution or a TMAH solution. The SCl solution removes the slags 12a by oxidation and micro-etching. The SCl solution includes ammonia (NH₃·H₂O), hydrogen peroxide (H₂O₂) and water (H₂O), here NH₃·H₂O:H₂O₂:H₂O is for example in a ratio of 1:1:5 to 1:2:7. The TMAH solution is for example a 2.58% TMAH solution, and other wet etching solutions may also be used, which are not limited in the embodiment. When the dry etching process is used, an etching gas used in the dry etching process is for example CF₄, CHF₃, Ar, or O₂.

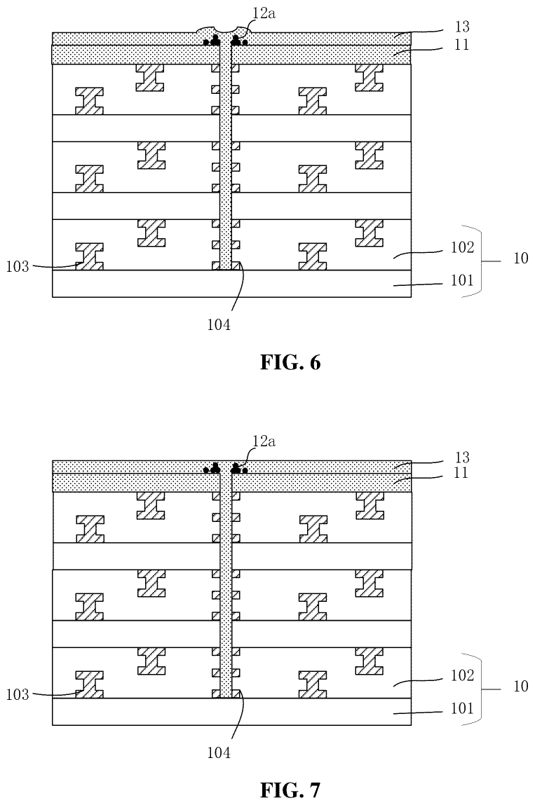

With reference to FIG. 6, in operation S40, a second oxide layer 13 is filled in the first trench, the second oxide layer 13 fully fills the first trench 12 and covers the first oxide layer 11. The second oxide layer 13 is formed by using the CVD process. Since the slags 12a are present on the first oxide layer at both sides of the top of the first trench, the second oxide layer on the slags may form protrusions when the second oxide layer is formed, and thus the second oxide layer may show an uneven surface. However, the hybrid bonding interface requires a flat surface, therefore it needs to planarize the second oxide layer.

With reference to FIG. 7, in operation S50, a surface of the second oxide layer 13 is planarized. In the embodiment, the surface of the second oxide layer 13 is planarized by way of using CMP, and protrusions and recesses on the surface of the second oxide layer 13 are removed.

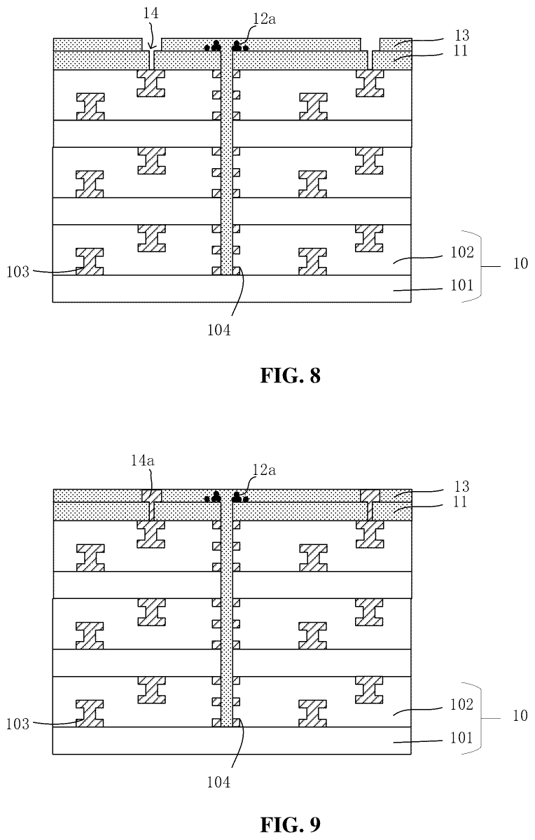

With reference to FIG. 8 and FIG. 9, in operation S60, a hybrid bonding interface is formed on the second oxide layer. The operation of forming the hybrid bonding interface on the second oxide layer includes the following operations S61 and S62.

In operation S61, with reference to FIG. 8, vias 14 are formed in the first oxide layer and the second oxide layer, the vias 14 penetrate through the first oxide layer 11 and the second oxide layer 13, and the formed via 14 is in a shape which is narrow at a lower portion thereof and wide at an upper portion thereof. When the vias 14 are formed, an etching stop layer (not shown in the figure) is also formed between the dielectric layer of the topmost wafer and the first oxide layer 11, and the etching stop layer is for example silicon nitride. First, a first patterned photoresist layer (not shown in the figure) is formed on the second oxide layer 13. The first oxide layer 11 and the second oxide layer 13 are etched by using the first patterned photoresist layer as a mask, to form first openings. The first openings penetrate through the first oxide layer 11 and the second oxide layer 13 and stop on the etching stop layer, and the first openings are aligned with the interconnection structures 103 in the dielectric layer of the topmost wafer respectively. The residual first patterned photoresist layer is removed. A bottom anti-reflective coating (BARC) is formed in the first opening, and the BARC extends to the surface of the second oxide layer 13. A second patterned photoresist layer is formed on a surface of the BARC. The etching stop layer, the first oxide layer 11 and the second oxide layer 13 continue to be etched by using the second patterned photoresist layer as a mask. The first openings extend into the etching stop layer, second openings are formed, and width of each of the second openings is greater than width of a respective one of the first openings. The second openings penetrate through the second oxide layer 13 and stop on the first oxide layer. Each of the first openings and a respective one of the second openings form a respective one of the vias 14, and the vias 14 penetrate through the etching stop layer and stop on the interconnection structure 103.

In operation S62, with reference to FIG. 9, conductive bonding pads 14a are formed in the vias 14 respectively. Metal materials are deposited in the vias 14 respectively, and the metal materials fully fill the vias 14 respectively and cover the second oxide layer 13. Then, the metal material on the second oxide layer 13 is removed by using an electro-chemical plating (ECP) or CMP process, to form the conductive bonding pads 14a and form a flat hybrid bonding interface. In the hybrid bonding interface, the second oxide layer and the first oxide layer are used for insulation, and are also referred to as insulation bonding layers. The conductive bonding pads 14a are located in the first oxide layer and the second oxide layer, and are interconnected with the interconnection structures 103 respectively. In general, the conductive bonding pads 14a are formed on the interconnection structures 103 respectively, and are interconnected with top metal layers of the interconnection structures 103 respectively, to achieve electrical leading-out from the interconnection structures. Materials of the conductive bonding pads 14a may be bonding metal materials, such as copper, gold, or a combination thereof.

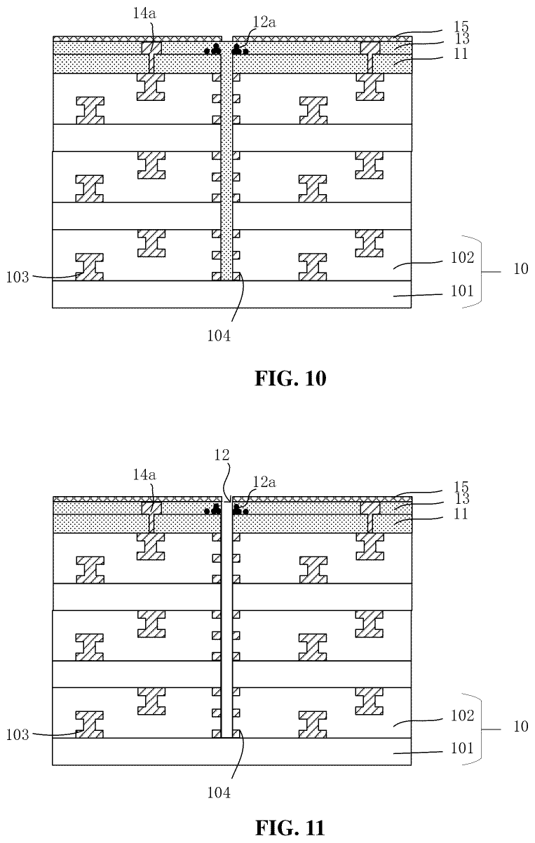

With reference to FIG. 10 and FIG. 11, in operation S70, the second oxide layer 13 in the first trench is removed. With reference to FIG. 10, before the second oxide layer 13 in the first trench is removed, a third patterned photoresist 15 is formed on the hybrid bonding surface, and the third patterned photoresist 15 exposes the second oxide layer 13 in the first trench. With reference to FIG. 11, the second oxide layer 13 in the first trench is etched by using the third patterned photoresist 15 as a mask. In the embodiment, the second oxide layer 13 in the first trench is removed by using a dry etching process.

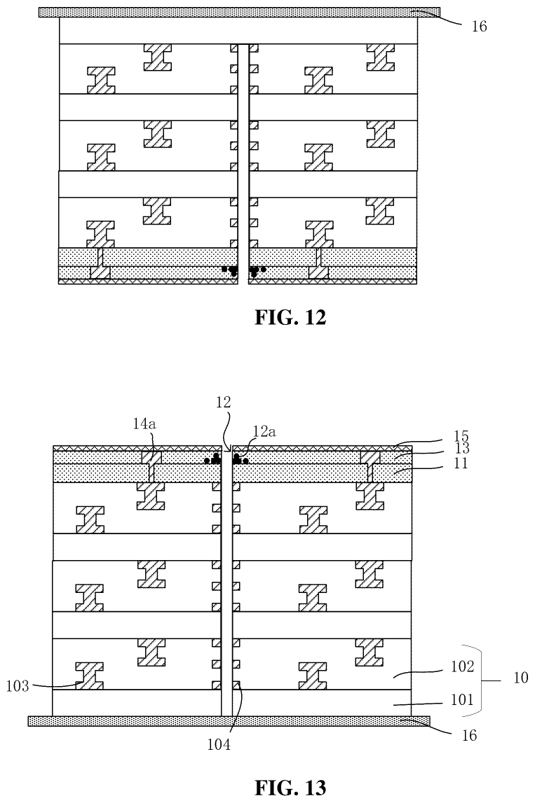

With reference to FIG. 12, in operation S80, a fixing film 16 is attached to a side of the substrate of the bottommost wafer, and the side of the substrate is away from the hybrid bonding interface. The wafer bonding structure is placed upside down on a platform (not shown in the figure). The platform is recessed in the middle thereof, and the film is attached in a non-contact manner. The third patterned photoresist 15 does not contact a surface of the platform. The fixing film 16 is attached to the side of the substrate of the bottommost wafer, and the side of the substrate is away from the hybrid bonding interface. The wafer bonding structure is attached to the fixing film 16, to ensure that diced chips are separated completely and do not fall off, either. The fixing film 16 is an organic matter, and the fixing film 16 is for example a UV film.

With reference to FIG. 13, in operation S90, the substrate of the bottommost wafer is diced. In the embodiment, the substrate of the bottommost wafer is diced by using a plasma dicing process, a cutter wheel dicing process or a stealth dicing process, to form chiplets. It should be noted that when the stealth dicing process is used, it is unnecessary to perform photolithography processes in operation S70.

After dicing of the wafer bonding structure completes, a cleaning process is performed on the chiplets to remove the third patterned photoresist, the organic matter, particles, or other substances.

In summary, it may be seen that in the method for wafer dicing provided in the embodiment of the disclosure, a wafer bonding structure is provided, here the wafer bonding structure includes at least two wafers stacked in sequence; a first oxide layer is formed as a protective layer, and a first trench which penetrates through at least one wafer and exposes a substrate of a bottommost wafer is formed; then a second oxide layer which fully fills the first trench and covers the first oxide layer is formed, the second oxide layer is planarized, and a planarized hybrid bonding interface is formed; then the second oxide layer in the first trench is removed, and the substrate of the bottommost wafer is diced, so that the problem where when the multi-layer stacked wafer is diced, layers sandwiched between the low dielectric-constant layer which needs to be removed by laser grooving and the Si substrate are too thick, and accumulation of slags is serious, resulting in inability of effectively removing the slags later, may be solved.

The above descriptions are only descriptions of preferred embodiments of the disclosure, and do not limit the scope of the disclosure in any way. Any variation or modification made by those of ordinary skill in the field of the disclosure according to the above disclosed contents should fall within the scope of protection of the claims.

We claim:

1. A method for wafer dicing, comprising:
providing a wafer bonding structure, wherein the wafer bonding structure comprises at least two wafers stacked in sequence, each of the wafers comprises a substrate, a dielectric layer formed on the substrate, and a dicing lane test structure formed in the dielectric layer;
forming a first oxide layer on a dielectric layer of a topmost wafer of the wafer bonding structure;
performing dicing along a dicing lane test structure of the topmost wafer, to form a first trench in the wafer bonding structure, wherein the first trench penetrates through at least one wafer and exposes a substrate of a bottommost wafer;
removing residual slags in the first trench after the first trench is formed;
filling a second oxide layer in the first trench, wherein the second oxide layer fully fills the first trench and covers the first oxide layer;
planarizing a surface of the second oxide layer;
forming a hybrid bonding interface on the second oxide layer;
removing the second oxide layer in the first trench;
attaching a fixing film to a side of the substrate of the bottommost wafer of the wafer bonding structure, and the side of the substrate being away from the hybrid bonding interface; and
dicing the substrate of the bottommost wafer.

2. The method for wafer dicing of claim 1, wherein thickness of the first oxide layer is equal to or greater than 0.05 μm.

3. The method for wafer dicing of claim 1, wherein the residual slags in the first trench are removed by using an etching process.

4. The method for wafer dicing of claim 1, wherein the first trench is formed by using a laser dicing process.

5. The method for wafer dicing of claim 1, wherein the first oxide layer and the second oxide layer are formed by using a chemical vapor deposition (CVD) process.

6. The method for wafer dicing of claim 1, wherein the surface of the second oxide layer is planarized by using a chemical mechanical polishing (CMP) manner.

7. The method for wafer dicing of claim 1, wherein forming the hybrid bonding interface on the second oxide layer comprises:
forming vias in the first oxide layer and the second oxide layer, wherein the vias penetrate through the first oxide layer and the second oxide layer; and
forming conductive bonding pads in the vias respectively.

8. The method for wafer dicing of claim 1, wherein the second oxide layer in the first trench is removed by using a dry etching process.

9. The method for wafer dicing of claim 1, wherein the substrate of the bottommost wafer is diced by using a plasma dicing process.
